(19) United States
(12) Patent Application Publication
(10) Pub. No.: US 2013/0168668 A1
(43) Pub. Date: Jul. 4, 2013

(54) THIN FILM TRANSISTOR ARRAY SUBSTRATE, METHOD FOR MANUFACTURING THE SAME, AND ANNEALING OVEN FOR PERFORMING THE SAME METHOD

(71) Applicants: Wei-Chou LAN, HSINCHU (TW); Ted-Hong SHINN, HSINCHU (TW); Hsing-Yi WU, HSINCHU (TW)

(72) Inventors: Wei-Chou LAN, HSINCHU (TW); Ted-Hong SHINN, HSINCHU (TW); Hsing-Yi WU, HSINCHU (TW)

(73) Assignee: E INK HOLDINGS INC., HSINCHU (TW)

(21) Appl. No.: 13/615,651

(22) Filed: Sep. 14, 2012

Related U.S. Application Data
(60) Provisional application No. 61/581,095, filed on Dec. 29, 2011.

(30) Foreign Application Priority Data
May 16, 2012 (TW) 101117421

(51) Int. Cl. H01L 27/12; F27D 7/06; F27B 9/02; H01L 21/84; F27D 19/00

(52) U.S. Cl. 257/43; 438/104; 432/37; 432/128; 257/E27.112; 257/E21.7

(57) ABSTRACT

A thin film transistor (TFT) array substrate includes a substrate, a gate electrode layer disposed on the substrate, an insulating layer, an oxide semiconductor layer disposed on the insulating layer, a source/drain electrode layer, an organic-acrylic photoresist layer, a passivation layer and an electrically conductive layer. The insulating layer is disposed on the gate electrode layer and the substrate. The source/drain electrode layer is disposed on the insulating layer and the oxide semiconductor layer, and a gap is formed through the source/drain electrode layer for exposing the oxide semiconductor layer therethrough. The organic-acrylic photoresist layer covers the source/drain electrode layer. The passivation layer is disposed on the substrate, the oxide semiconductor layer and the organic-acrylic photoresist layer. The electrically conductive layer is disposed on the passivation layer or the organic-acrylic photoresist layer and connected to the source/drain electrode layer or the gate electrode layer.

### RELATED APPLICATIONS

This application claims priority to U.S. Provisional Application Ser. No. 61/581,095 filed Dec. 29, 2011, and Taiwan Application Serial Number 101117421, filed May 16, 2012, the disclosures of which are incorporated herein by reference in their entireties.

### BACKGROUND

1. Field of Invention

The present invention relates to a thin film transistor (TFT) array substrate and a method for manufacturing the same. More particularly, the present invention relates to a TFT array substrate for display devices and a method for manufacturing the same.

2. Description of Related Art

Recently, a transparent amorphous oxide semiconductor film comprising indium, gallium, zinc, and oxygen is used as a channel layer for a thin film transistor.

During a semiconductor process, since a semiconductor doped with an impurity such as boron, phosphorous, or arsenic, etc. may produce a lot of vacancies to result in atom arrangement disorders changing material properties of the semiconductor severely, an annealing process is required to recover the lattice structure and eliminate defects, and to make the semiconductor doped with an impurity from clearance position into substitution position by the annealing process. And then the main purpose of the annealing is to fix the V-TH shift problem caused by the transparent amorphous oxide losing the oxygen.

If an organic protection layer is used as a passivation layer or a photoresist because the organic passivation layer cannot resist high temperature resistance when the annealing process is performed in oxygen-containing ambiance, source/drain metals will be oxidized at the same time, thus resulting in the increase of conductor resistance and even uniform line resistance.

In addition, high concentration of oxygen is used as reaction gas for the annealing process. Since it is likely for the high concentration of oxygen to case sever oxidization, such as combustion or even explosion, an annealing oven has to be further designed with a safety design.

Therefore, there is a need to develop a TFT array substrate, a method for manufacturing the same, and annealing oven for the same method, thereby overcoming the foregoing disadvantages.

### SUMMARY

The following presents a summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In accordance with an embodiment of the present invention, a thin film transistor (TFT) array substrate includes a substrate, a gate electrode layer, an insulating layer, an oxide semiconductor layer, a source/drain electrode layer, an organic-acrylic photoresist layer, a passivation layer, and an electrically conductive layer. The gate electrode layer is disposed on the substrate. The insulating layer is disposed on the gate electrode layer and the substrate. The oxide semiconductor layer is disposed on the insulating layer. The source/drain electrode layer is disposed on the insulating layer and the oxide semiconductor layer, and a gap is formed through the source/drain electrode layer for exposing the oxide semiconductor layer therethrough. The organic-acrylic photoresist layer covers the source/drain electrode layer. The passivation layer is disposed on the substrate, the oxide semiconductor layer and the organic-acrylic photoresist layer. The electrically conductive layer is disposed on the passivation layer or the organic-acrylic photoresist layer, and is connected to the source/drain electrode layer or the gate electrode layer.

According to another embodiment disclosed herein, the oxide semiconductor layer includes an amorphous oxide, and the amorphous oxide includes indium, zinc, and gallium.

According to another embodiment disclosed herein, the electrically conductive layer includes an indium tin oxide.

According to another embodiment disclosed herein, the passivation layer is an organic passivation layer.

In accordance with an embodiment of the present invention, a method for manufacturing a TFT array substrate is described as follows. A substrate is provided. A gate electrode layer is formed to cover the substrate, and an insulating layer is formed to cover the substrate and the gate electrode layer, and an oxide semiconductor layer is formed to cover the insulating layer. A source/drain electrode layer is formed on the oxide semiconductor layer and the insulating, layer, and a gap is formed through the source/drain electrode layer for exposing the oxide semiconductor layer therethrough. An organic-acrylic photoresist layer is formed to cover the source/drain electrode layer, and the oxide semiconductor layer is annealed in a condition having a fixed oxygen concentration. A passivation layer is formed on the substrate, the oxide semiconductor layer and the organic-acrylic photoresist after the oxide semiconductor layer is annealed. An electrically conductive layer is formed on the passivation layer or the organic-acrylic photoresist layer after the passivation layer and the organic-acrylic photoresist layer are etched, and the electrically conductive layer is electrically connected to the source/drain electrode layer or the gate electrode layer.

According to another embodiment disclosed herein, the etch process is a dry etching process.

According to another embodiment disclosed herein, the dry etching process is a plasma etching process.

According to another embodiment disclosed herein, the oxide semiconductor layer includes an amorphous oxide, and the amorphous oxide includes indium, zinc, and gallium.

According to another embodiment disclosed herein, the electrically conductive layer includes an indium tin oxide.

According to another embodiment disclosed herein, the passivation layer is an organic passivation layer.

In accordance with an embodiment of the present invention, an annealing oven for performing the method for manufacturing a TFT array substrate includes a first housing, a second housing, a first chamber, a second chamber, an alarming control device, and a pressure control device. The second housing encloses the first housing. The first chamber is filled with oxygen and the second chamber is filled with an inert gas. The first gas channel is connected between the first chamber and the first housing for transporting the oxygen from the first chamber to the first housing. One end of the second gas channel is connected to the second chamber, and another end of the second gas channel separated into a first branch portion and a second branch portion, in which the first branch portion is connected to the first housing, and the second branch portion is connected to the second housing for transporting the inert gas from the second gas chamber to the second housing, and the first housing. The alarming control device includes a gas-detecting device, an alarming device, and several gas flow control valves. The gas-detecting device is disposed on the first housing for detecting a concentration ratio of the oxygen to the inert gas. The alarming device is connected to the gas-detecting device for issuing an alarming signal. The gas flow control valves are disposed on the first branch portion of the second gas channel and the first has channel, and the gas flow control valves are connected to the gas-detecting device and the alarming device for controlling a flow rate of the oxygen and the inert gas into the first housing. The pressure control device is connected to the first housing and the second housing for controlling an inner pressure of the first housing and an inner pressure of the second housing.

According, to another embodiment disclosed herein, the annealing oven further includes a main gas channel, one end of the main gas channel is connected to the first branch portion of the second gas channel and the first gas channel and another end of the main gas channel is connected to the first housing.

Thus, the TFT array substrate of the embodiment of the present invention uses an organic-acrylic photoresist for covering a source/drain electrode layer to protect the source/drain electrode layer in an annealing process, such that oxidization of the source/drain electrode layer causing a line impendence rising, even a problem of a line impendence inequality can be avoided.

In addition, the annealing oven of the embodiment of the present invention has the alarming control device to adjust the oxygen concentration, such that the explosion caused by the oxidation reaction expanding can be avoided.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description serve to explain the principles of the invention. In the drawings,

FIG. 1 illustrates a schematic cross-sectional view of a TFT array substrate according to an embodiment of the present invention;

FIGS. 2A-2C are cross-sectional views schematically illustrating process steps for manufacturing a TFT array substrate according to an embodiment of the present invention; and

FIG. 3 illustrates a schematic view of an annealing oven for performing the method for manufacturing a thin film transistor array substrate.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

An embodiment of the present invention provides a thin film transistor array substrate that provides an organic-acrylic photoresist for covering a source/drain electrode layer to protect the source/drain electrode layer in an annealing process, thereby ultimately preventing the source/drain electrode layer from being oxidized.

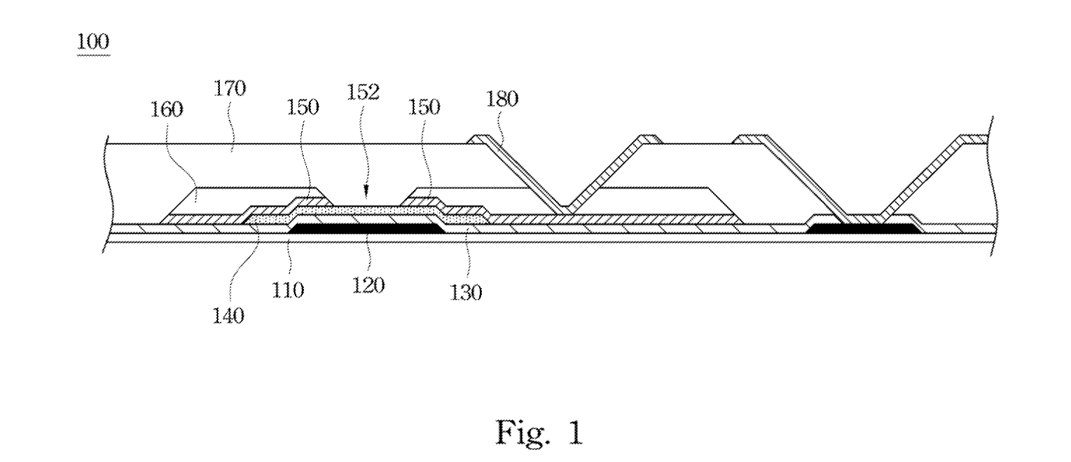

Referring FIG. 1. FIG. 1 illustrates a schematic cross-sectional view of a TFT array substrate 100 according to an embodiment of the present invention. The thin film transistor array substrate 100 includes a substrate 110, a gate electrode layer 120, an insulating layer 130, an oxide semiconductor layer 140, a source/drain electrode layer 150, an organic-acrylic photoresist layer 160, a passivation layer 170, and an electrically conductive layer 180.

The gate electrode layer 120 is disposed on the substrate 110. In this embodiment, the substrate 110 may be a resin substrate, an organic polymer substrate, or a glass substrate. The insulating layer 130 is disposed on the gate electrode layer 120 and the substrate 110. The oxide semiconductor layer 140 is disposed on the insulating layer 130. In this embodiment, the oxide semiconductor layer 140 includes an amorphous oxide. In another embodiment, the amorphous oxide includes indium, zinc and gallium.

The source/drain electrode layer 150 is disposed on the insulating layer 130 and the oxide semiconductor layer 140, in which a gap 152 is formed through the source/drain electrode layer 150, and the oxide semiconductor layer 140 is exposed through the gap 152. The organic-acrylic photoresist layer 160 covers the source/drain electrode layer 150.

The passivation layer 170 is disposed on the substrate 110, the oxide semiconductor layer 140, and the organic-acrylic photoresist layer 160. In this embodiment, the passivation layer 140 is an organic passivation layer. After the passivation layer 170 is patterned by dry etching, the electrically conductive layer 180 is disposed on the passivation layer 170 or the organic-acrylic photoresist layer 160, and is connected to the source/drain electrode layer 150 or the gate electrode layer 120.

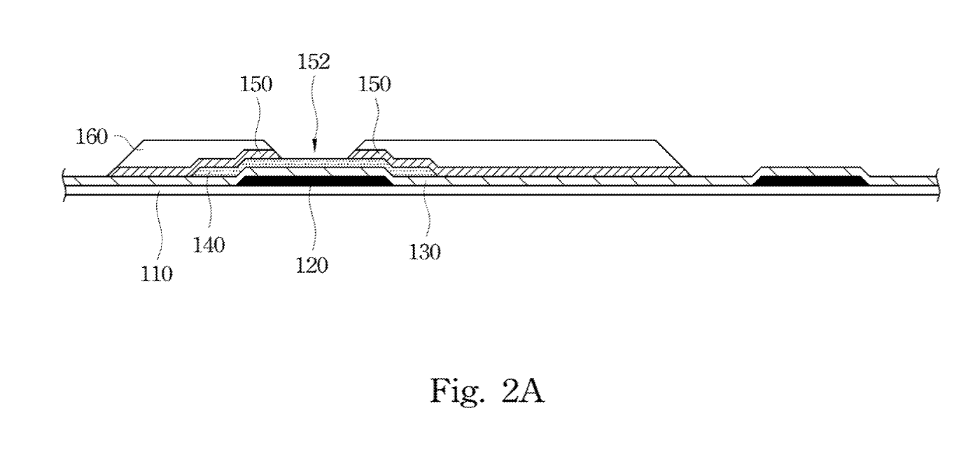

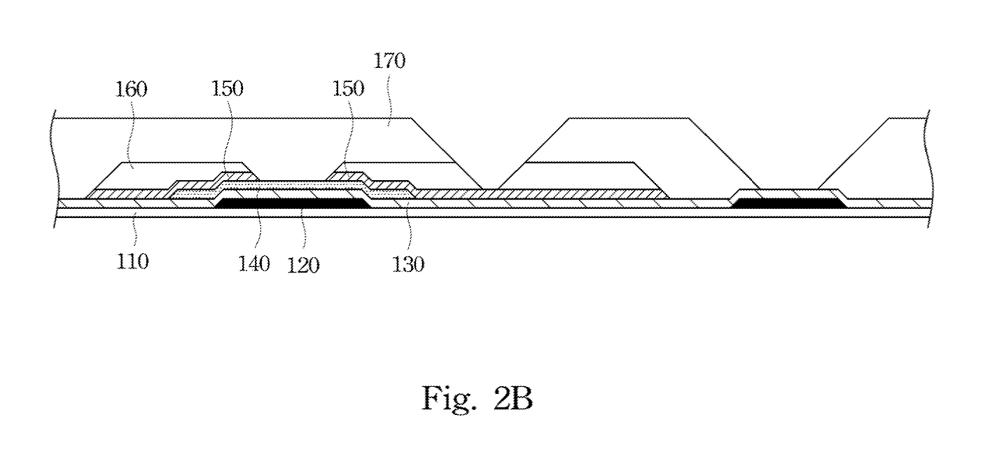

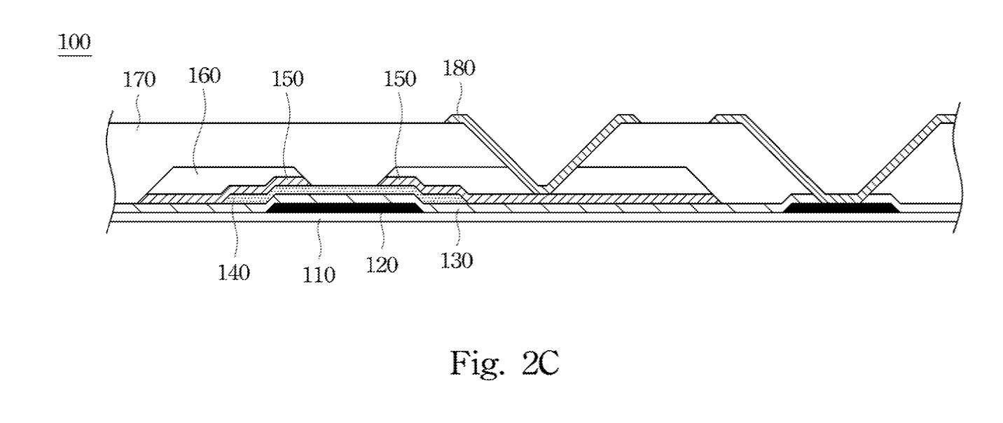

FIGS. 2A-2C illustrate cross-sectional views schematically illustrating process steps for manufacturing a TFT array substrate 100 according to an embodiment of the present invention.

Referring to FIG. 2A, a gate electrode layer 120 is formed to cover a substrate 110; an insulating layer 130 is formed to cover the substrate 110 and the gate electrode layer 120; and an oxide semiconductor layer 140 is formed to cover the insulating layer 130. In this embodiment, the substrate 110 may be a resin substrate, an organic polymer substrate, or a glass substrate. In this embodiment, the oxide semiconductor layer 140 includes an amorphous oxide. In another embodiment, the amorphous oxide includes indium, zinc and gal hum.

A source/drain electrode layer 150 is formed on the oxide semiconductor layer 140 and the insulating layer 130, in which a gap 152 is formed through the source/drain electrode layer 150, such that the oxide semiconductor layer 140 is exposed through the gap 152.

An organic-acrylic photoresist layer 160 is formed to cover the source/drain electrode layer 150, and the oxide semiconductor layer 140 is annealed in an ambience with a fixed oxygen concentration. In this embodiment, the oxide semiconductor layer 140 is annealed in an annealing oven filled with oxygen and inert gas, and an inner temperature of the annealing oven is 300° C.˜500° C. Furthermore, the organic-acrylic photoresist 160 may have high temperature resistance to protect the source/drain electrode layer 150 against the oxidization. The annealing process in an annealing oven filled with oxygen and inert gas results in atom arrangement disorders changing material properties of the oxide semiconductor layer 140 to solve the V-TH shift problem caused by the oxide semiconductor layer 140 losing the oxygen. In addition, the organic-acrylic photoresist 160 having high temperature resist is capable of covering a source/drain electrode layer 150, thus the organic-acrylic photoresist 160 can protect the source/drain electrode layer 150 in an annealing process, such that oxidization of the source/drain electrode layer 150 causing a line impendence rising, even a problem of a line impendence inequality can be avoided.

Referring to FIG. 28, a passivation layer 170 is formed on the substrate 110, the oxide semiconductor layer 140 and the organic-acrylic photoresist 160 after the oxide semiconductor layer 140 is annealed. In this embodiment, the passivation layer 170 is an organic passivation layer for being a stopping Slayer in a etch process. In this embodiment, the organic-acrylic photoresist 160 is not removed after the oxide semiconductor layer 140 is annealed. In another embodiment, the organic-acrylic photoresist 160 may be removed after the oxide semiconductor layer 140 is annealed in accordance with actual requirements.

Referring to FIG. 2C, a electrically conductive layer 180 is formed on the passivation layer 170 on which an etching process or the organic-acrylic photoresist layer 160 that has completed the etching process has been completed, and the electrically conductive layer 180 is electrically connected to the source/drain electrode layer 150 or the gate electrode layer 120. In this embodiment, the electrically conductive layer 180 is directly adhered to the passivation layer 170 by vacuum sputtering, and is connected to the source/drain electrode layer 150 or the gate electrode layer 120. In this embodiment, the electrically conductive layer 180 may be an indium tin oxide for transmitting electrical signals. Furthermore, the etch process may be a dry etching process, and the dry etching, process may be a plasma etching process. However, in other embodiments, the etch process may be the other etching process.

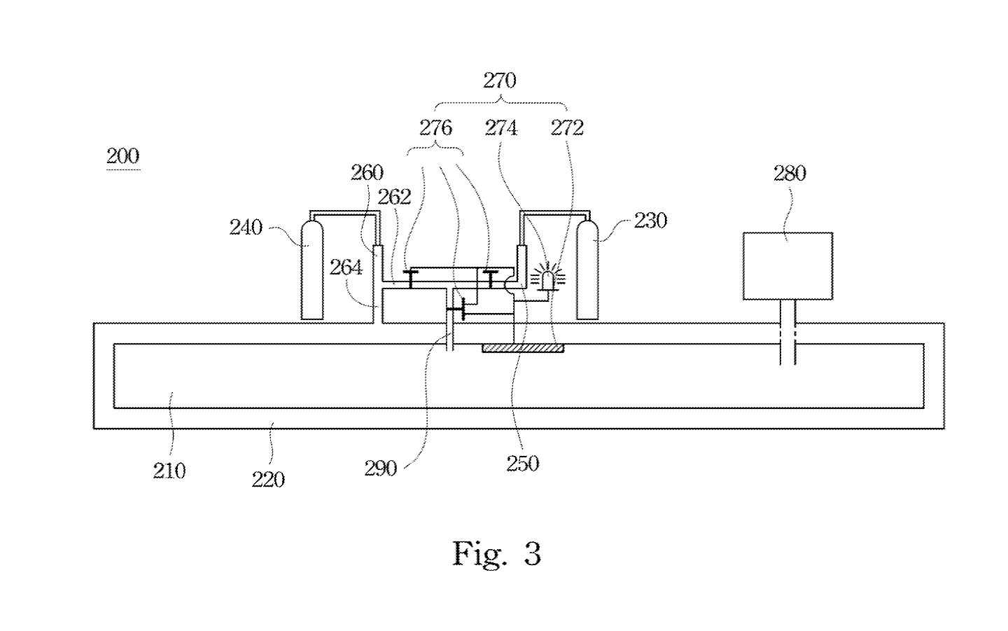

FIG. 3 illustrates a schematic view of an annealing oven for performing the method for manufacturing a TFT array substrate. An annealing oven 200 for performing the method for manufacturing a TFT array substrate includes a first housing 210, a second housing 220, a first chamber 230, a second chamber 240, a first gas channel 250, a second gas channel 260, an alarming control device 270, and a pressure control device 280.

The second housing 220 encloses the first housing 210. The first chamber 230 is filled with oxygen, and the second chamber 240 is filled with an inert gas. In an embodiment, the inert gas is nitrogen. The first gas channel 250 is connected between the first chamber 230 and the first housing 210 for transporting the oxygen from the first chamber 230 to the first housing 210. One end of the second gas channel 260 is connected to the second chamber 240, and another end of the second gas channel 260 is extended to a first branch portion 262 and a second branch portion 264, in which the first branch portion 262 is connected to the first housing 210, and the second branch portion 264 is connected to the second housing 220 for transporting the inert gas from the second gas chamber 240 to the second housing 220 and the first housing 210. The inert gas of the second housing 220 may prevent an explosion caused by expansion of the oxygen in the first housing 210.

The alarming control device 270 includes a gas-detecting device 272, an alarming device 274, and several gas flow control valves 276. The gas-detecting device 272 is disposed on the first housing 210 for detecting a concentration ratio of the oxygen to the inert gas. The alarming device 274 is connected to the gas-detecting device 272 for issuing an alarming signal. The gas flow control valves 276 are disposed on the first branch portion 262 of the second gas channel 260 and the first gas channel 250, and are connected to the gas-detecting device 272 and the alarming device 274 for controlling a flow rate of the oxygen and the inert gas into the first housing 210. In this embodiment, an end of the main gas channel 290 simultaneously is connected to the first branch portion 262 of the second gas channel 260 and the first gas channel 250. Another end of the main gas channel 290 is connected to the first housing 210.

The pressure control device 280 is connected to the first housing 210 and the second housing 220 for controlling an inner pressure of the first housing 210 and an inner pressure of the second housing 220. For example, when an inner pressure of the first housing 210 or an inner pressure of the second housing 220 is too high, the pressure control device 280 may detect the pressure thereof and exhaust the gas (the oxygen or the inert gas) to maintain the inner pressure of the first housing 210 or an inner pressure of the second housing 220 to be stable.

According to above-described embodiments, utilizing the embodiment of the invention has the following advantages:

(1) The thin film transistor array substrate of the embodiment of the present invention has an organic-acrylic photoresist for covering a source/drain electrode layer to thereby protect the source/drain electrode layer in an annealing process, such that oxidization of the source/drain electrode layer causing a line impendence rising, even a problem of a line impendence inequality can be avoided.

(2) The annealing oven of the embodiment of the present invention has the alarming control device to adjust the oxygen concentration, such that the explosion caused by the oxidation reaction expanding can be avoided.

It will be apparent to those skilled in the art that various modifications and variations can be made to the structure of the present invention without departing from the scope or spirit of the invention. In view of the foregoing, it is attended that the present invention cover modifications and variations of this invention provided they fall within the scope of the following claims and their equivalents.

What is claimed is:

1. A thin film transistor array substrate comprising:
a substrate;
a gate electrode layer disposed on the substrate;
an insulating layer disposed on the gate electrode layer and the substrate;
an oxide semiconductor layer disposed on the insulating layer;
source/drain electrode layer disposed on the insulating layer and the oxide semiconductor layer, wherein a gap formed through the source/drain electrode layer for exposing the oxide semiconductor layer;
an organic-acrylic photoresist layer covering the source/drain electrode layer;
a passivation layer disposed on the substrate, the oxide semiconductor layer and the organic-acrylic photoresist layer; and
an electrically conductive layer disposed on the passivation layer or the organic-acrylic photoresist layer and connected to the source/drain electrode layer or the gate electrode layer.

2. The thin film transistor array substrate of claim 1, wherein the oxide semiconductor layer comprises an amorphous oxide, and the amorphous oxide comprises indium, zinc, and gallium.

3. The thin film transistor array substrate of claim 1, wherein the electrically conductive layer comprises an indium tin oxide.

4. The thin film transistor array substrate of claim 1, wherein the passivation layer is an organic passivation layer.

5. A method for manufacturing an thin film transistor array substrate comprising:
(a) providing a substrate;
(b) forming a gate electrode layer to cover the substrate; forming an insulating layer to cover the substrate and the gate electrode layer; and forming an oxide semiconductor layer to cover the insulating layer;
(c) forming a source/drain electrode layer on the oxide semiconductor layer and the insulating layer; and forming a gap through the source/drain electrode layer to expose the oxide semiconductor layer;
(d) forming an organic-acrylic photoresist layer to cover the source/drain electrode layer; and annealing the oxide semiconductor layer in an ambience with a fixed oxygen concentration;
(e) forming a passivation layer on the substrate, the oxide semiconductor layer and the organic-acrylic photoresist after annealing the oxide semiconductor layer;
(f) forming, an electrically conductive layer on the passivation layer or the organic-acrylic photoresist layer after etching the passivation layer and the organic-acrylic photoresist layer; and electrically connecting the electrically conductive layer to the source/drain electrode layer or the gate electrode layer.

6. The method of claim 5, wherein the etch process is a dry etching process.

7. The method of claim 6, wherein the dry etching process is a plasma etching process.

8. The method of claim 5, wherein the oxide semiconductor layer comprises an amorphous oxide, and the amorphous oxide comprises, indium, zinc, and gallium.

9. The method of claim 5, wherein the electrically conductive layer comprises an indium tin oxide.

10. The method of claim 5, wherein the passivation layer is an organic passivation layer.

11. An annealing oven for executing the step (d) of the method of claim 5, the annealing oven comprising:
a first housing and a second housing enclosing the first housing;
a first chamber and a second chamber, wherein the first chamber is filled with oxygen, and the second chamber is filled with an inert gas;
a first gas channel connected between the first chamber and the first housing for transporting the oxygen from the first chamber to the first housing;
a second gas channel, one end of the second gas channel connected to the second chamber and another end of the second gas channel extended to a first branch portion and a second branch portion, wherein the first branch portion is connected to the first housing and the second branch portion is connected to the second housing for transporting the inert gas from the second gas chamber to the second housing and the first housing;
an alarming control device, comprising:
a gas-detecting device disposed on the first housing for detecting a concentration ratio of the oxygen to the inert gas;
an alarming device connected to the gas-detecting device for issuing an alarming signal; and
a plurality of gas flow control valves disposed on the first branch portion of the second gas channel and the first gas channel and connected to the gas-detecting device and the alarming device for controlling a flow rate of the oxygen and the inert gas into the first housing; and
a pressure control device connected to the first housing and the second housing for controlling an inner pressure of the first housing and an inner pressure of the second housing.

12. The annealing oven of claim 11, further comprising a main gas channel, one end of the main gas channel connected to the first branch portion of the second gas channel and the first gas channel and another end of the main gas channel connected to the first housing.
